(19) United States
(12) Patent Application Publication
(10) Pub. No.: US 2007/0120138 A1
(43) Pub. Date: May 31, 2007

(54) Multi-layer light emitting device with integrated thermoelectric chip

(75) Inventors: Edwin S. Sayers, Saline, MI (US); James D. Tarne, West Bloomfield, MI (US); Paul A. Lyon, Ann Arbor, MI (US)

Correspondence Address: VISTEON, C/O BRINKS HOFER GILSON & LIONE, PO BOX 10395, CHICAGO, IL, 60610, US

(73) Assignee: Visteon Global Technologies, Inc.

(21) Appl. No.: 11/287,601

(22) Filed: Nov. 28, 2005

(51) Int. Cl. H01L 33/00

(52) U.S. Cl. 257/99

(57) ABSTRACT

A LED package having an LED chip and a thermoelectric device. The thermoelectric device a has a first side in thermal communication with the LED chip and a second side in thermal communication with a heat sink to create a thermal gradient between the LED chip and the heat sink. The thermoelectric device is coupled in electrical series with the LED chip and powered such that a current provided the thermoelectric device is proportional to a drive current of the LED chip.

### BACKGROUND

1. Field of the Invention

The present invention generally relates to a light emitting diode (LED). More specifically, the invention relates to a mechanism for cooling the LED.

2. Description of Related Art

A white LED assembly typically includes a chip, a phosphor conversion layer and a housing. The process of producing light from electrical power is somewhat inefficient at approximately 10% efficiency, the rest of the electrical power is converted to heat energy. Therefore, the temperature of the chip will rise as the LED chip produces light. With this temperature increase, the amount of light produced decreases, particularly in terms of lumens per watt of electrical drive power. If the temperature continues to rise, eventually, the LED chip will fail as the actual chip temperature will exceed the maximum junction temperature for the chip. Currently, the use of the heat sinks, spacing of heat generating devices, and convection cooling are all used to reduce the temperature of the LED chip in an LED assembly. These techniques however, restrict the size and power of the LED assembly, thereby limiting the application of such assemblies.

In view of the above, it is apparent that there exists a need for an improved LED assembly.

### SUMMARY

In satisfying the above need, as well as overcoming the enumerated drawbacks and other limitations of the related art, the present invention provides such an improved LED assembly or package.

An LED package according to the principles of the present invention includes an LED chip and a thermoelectric device (TED) coupled thereto. The LED chip is covered with a conversion layer, typically a powder coating of phosphor, that is held in place by a transparent coating or a matrix material into which the phosphor is embedded. A thermoelectric device is integrated into the LED package in order to decrease the temperature of the chip and to increase the heat flux from the package into a heat sink. The heat is transferred by thermal conduction from the package slug to the heat sink through the circuit substrate. The thermoelectric device can be located under the silicon submount, under the chip, on top of the slug, and on top of the lead frame, depending on the LED package structure. The thermoelectric device can also be located on the bottom of the slug, in order to lower the temperature of the slug and nearly the entire package, while increasing the heat expelled from the package into the substrate and heat sink.

Further objects, features and advantages of this invention will become readily apparent to persons skilled in the art after a review of the following description, with reference to the drawings and claims that are appended to and form a part of this specification.

### BRIEF DESCRIPTION OF THE DRAWINGS

FIG. 1 is a side sectional view of an LED package according to the present invention; and

FIG. 2 is a side sectional view of another embodiment of an LED package according to the present invention.

### DETAILED DESCRIPTION

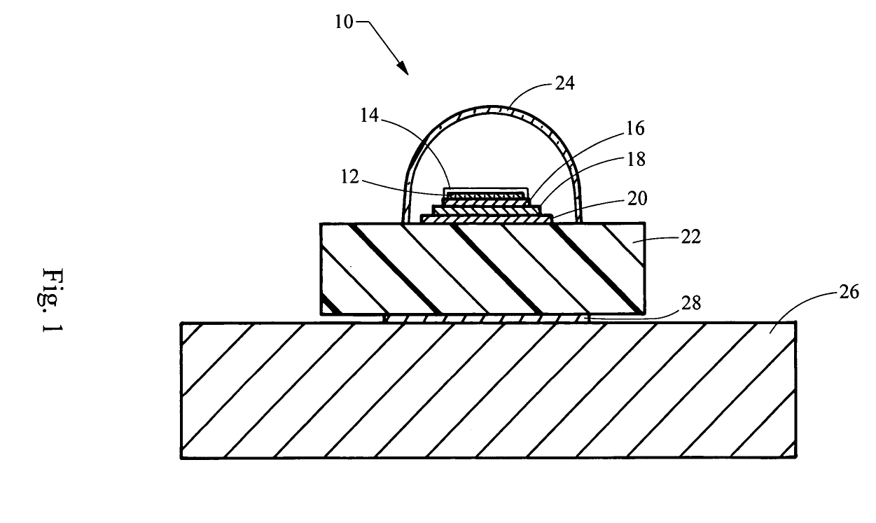

Referring now to FIG. 1, an LED chip package embodying the principles of the present invention is illustrated therein and designated at 10. As its primary components, the LED chip package 10 includes an LED chip 12 and a thermoelectric device 18.

The LED chip 12 is covered by a conversion coating layer 14 that is attached to a first side of the LED chip 12. The conversion coating layer 14 may be made of phosphor or other commonly used conversion coating material, and the light generated by the LED chip 12 is transmitted through the conversion coating layer 14. Attached to a second side of the LED chip 12 is a submount layer 16. The submount layer 16 may be made of silicon or any other material suitable for that purpose. Attached to the submount layer 16, opposite of the LED chip 12, is a thermoelectric device (TED) 18. The TED 18 is attached on a first side to the submount layer 16 and is configured to actively draw heat through the submount layer 16 and away from the LED chip 12. The second side of the TED 18 is attached to a slug layer 20. The slug layer 20 is made of a highly themoconductive material, so that the heat drawn from the LED chip 12 by the TED 18 can be effectively deposited into and dissipated through the slug layer 20. One preferred material for the slug layer 20 is copper because of its high thermal conductivity.

The slug layer 20 is in turn mounted to an LED housing 22. The LED housing 22 not only supports and protects the LED chip 12, but it also serves to further dissipate heat from the slug layer 20.

Attached to the LED housing 22 and surrounding the LED chip 12 is a lens 24. The lens 24 focuses the light generated by the LED chip 12 and also serves to protect the LED chip 12 and conversion coating layer 14.

The LED housing 22 may further be attached to a heat sink 26 through an attachment layer 28. The attachment layer 28 can be solder, a thermoconductive adhesive or similar material. Preferably, the heat sink 26 has a large surface area and mass, relatively speaking, and is configured to further dissipate the heat received from the LED housing 22 through convection. Accordingly, it is preferred that the heat sink 26 has a high thermal conductivity and, as such, may be made from copper or similar material.

As the LED chip 12 heats up during illumination, heat is transferred from the LED chip 12 to the submount layer 16, to the slug layer 20 and to the rest of the package. As the slug layer 20 increases in temperature, the heat from the slug layer 20 is transferred to the submount layer 16 onto which the LED chip 12 is mounted. The amount of heat dissipated from the LED package 10 and the resulting temperature of the LED chip 12 are contingent upon the package thermal resistance. The package thermal resistance is calculated as the difference in temperature of the LED chip 12 from the bottom of the slug layer 20 divided by the thermal power dissipation of the LED chip 12. Hence, if the slug layer 20 is at 60° C. and the LED chip 12 is at 100° C. while driving the LED chip 12 at 1 W, the resulting thermal resistance is 40° C./1 W or 40° C. /W.

The TED 18 aids the flow of heat from the LED chip 12. When mounted under the submount layer 16, the TED 18 reduces the temperature of the LED chip 12, which is attached to the “cold” side of the thermoelectric device 18. The heat is drawn through the “cold” side of the TED 18 and across a temperature gradient thereby increasing the temperature of the “hot” side of the TED 18. The “hot” side then conducts heat to the slug layer 20 due to the difference in temperature according to equation 1.
Q=mc(T₁−Tₐ)
Where Q is the heat energy, m is the mass of the body, c is the thermal capacitance, T1 is the induced temperature and Ta is the ambient temperature. Further, the change in the temperature over time is defined according to equation 2.
dQ/dt=(T₁−Tₐ)/Rₜₕ (2)
Where dQ/dt is the thermal power and Rₜₕ is the thermal resistance across the interface.

Also, the TED 18 creates a temperature gradient across it as a function of the input current. The voltage of the TED 18 is dependent on the existing temperature gradient:
dT_{ted}=h_{ted}(dT_{induced})Kₒ P_{ted} (3)
Where dT_{ted} is the reverse temperature gradient caused by the TED 18, h_{ted} is the efficiency of the TED 18, Kₒ is the power coefficient of temperature gradient, and dT_{induced} is the pre-existing temperature drop across the TED 18.

Therefore, the efficiency of the TED 18 is dependent on the induced temperature gradient and the temperature gradient created is dependent on the input power. Therefore, the higher the temperature difference across the TED 18 the lower its effectiveness. However, if the temperature gradient is relatively small, the efficiency is high and the temperature drop on the LED chip 12 can be created more efficiently. In this embodiment, the efficiency of the TED 18 is high enough that the amount of power required to create a reverse temperature gradient contributes more to the heat extraction than to heat input of the LED chip 12.

The TED 18 is powered in electrical series with the LED chip 12, making the current through the TED 18 proportional to the drive current of the LED chip 12. Accordingly, the current through the TED 18 is roughly proportional to the power dissipated in the LED chip 12. This allows the TED 18 to work only as hard as it is required.

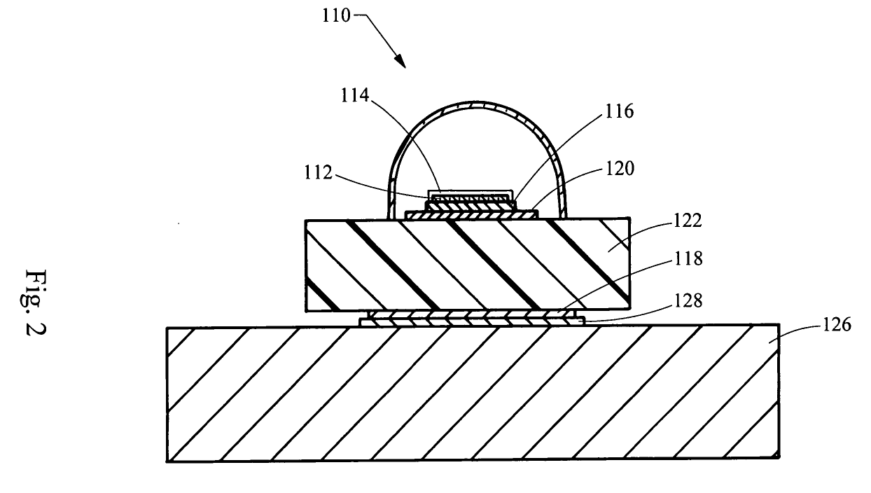

Referring now to FIG. 2, an alternative embodiment of an LED chip package according to the principles of the present invention is illustrated therein and designated at 110. The LED chip package 110 includes an LED chip 112 that is covered on a first side by a conversion coating layer 114. The conversion coating layer 114 may be made of phosphor or other material suitable for that purpose, and the light generated by the LED chip 112 is transmitted through this conversion coating layer 114.

Attached to a second side of the LED chip 112 is a submount layer 116 which may be made of silicon or other well known submount materials. Attached to the submount layer 116, opposite the LED chip 112, is a slug layer 120 of a highly themoconductive material. Based on this construction, heat from the LED chip 112 is effectively deposited into and dissipated through the slug layer 120. One material that is suitable for the slug layer 120 is copper because of its high thermal conductivity.

An LED housing 122 is attached to the slug layer 120 and protects the LED chip 112. The LED housing 122 also serves to further dissipate heat from the slug layer 120.

Attached to the LED housing 122 and surrounding the LED chip 112 is a lens 124. The lens 124 focuses the light generated by the LED chip 112 and in addition to the LED housing 122, also serves to protect the LED chip 112 and conversion coating layer 114.

Attached to the LED housing 122, opposite the LED chip 112, is a TED 118. The TED 118 is attached on a first side to the LED housing 122 and is configured to actively draw heat through the LED housing 122 and away from the LED chip 112. The second side of the TED 118 is attached to a heat sink 126 through an attachment layer 128.

As with the prior embodiment, the attachment layer 128 may be made of solder or a thermoconductive adhesive and the slug layer 120 is also a highly thermoconductive material. This enables heat drawn from the LED chip 112 by the TED 118 to be effectively deposited into and dissipated through the heat sink 126. Accordingly, the heat sink 126 is preferably made of copper or similar material. Additionally, the heat sink 126 has a large surface area and is configured to further dissipate the heat from the LED housing 122 through convection.

As discussed above in connection with the prior embodiment, the TED 118 is powered in electrical series with the LED chip 112, making the current through the TED 118 proportional to the drive current of the LED chip 112. Accordingly, the current through the TED 118 is roughly proportional to the power dissipated in the LED chip 112. This allows the TED 118 to work proportionally to the LED chip 112 and, therefore, only as hard as it is required.

As a person skilled in the art will readily appreciate, the above description is meant as an illustration of implementation of the principles this invention. This description is not intended to limit the scope or application of this invention in that the invention is susceptible to modification, variation and change, without departing from the spirit of this invention, as defined in the following claims.

We claim:

1. An LED chip package comprising:
an LED chip;
a heat sink; and
a thermoelectric device having a first side in thermal communication with the LED chip and a second side in thermal communication with the heat sink, the thermoelectric device being configured to create a thermal gradient between the LED chip and the heat sink, the LED chip and the thermoelectric device being in electrical communication, and wherein a current provided the thermoelectric device is based on a drive current of the LED chip.

2. The LED chip package according to claim 1, wherein the current provided to the thermoelectric device is proportional to the drive current of the LED chip.

3. The LED chip package according to claim 1, wherein the thermoelectric device is electrically connected in series with the LED chip.

4. The LED chip package according to claim 1, wherein the LED chip is mounted to a first side of a submount layer and the thermoelectric device is coupled opposite the LED chip on a second side of the submount layer.

5. The LED chip package according to claim 4, wherein the thermoelectric device is mounted to a first side of a slug layer that is opposite the submount layer, the thermoelectric device being mounted on a second side of the submount layer opposite the LED chip.

6. The LED chip package according to claim 5, wherein submount layer is silicon.

7. The LED chip package according to claim 1, wherein the thermoelectric device is located between the LED chip and a LED housing.

8. The LED chip package according to claim 1, wherein the LED chip is coupled to a LED housing and the LED housing is mounted to a first side of the thermoelectric device and a heat sink is mounted opposite the LED housing to a second side of the thermoelectric device.

9. An LED chip package comprising:
an LED chip, a thermoelectric device having a first side in thermal communication with the LED chip and a second side in thermal communication with a heat sink, the thermoelectric device being configured to create a thermal gradient between the LED chip and the heat sink, the LED chip being mounted to a first side of a submount layer and the thermoelectric device mounted opposite the LED chip on a second side of the submount layer;
the thermoelectric device being coupled in electrical series with the LED chip and powered such that a current provided the thermoelectric device is proportional to a drive current of the LED chip.

10. The LED chip package according to claim 9, wherein the thermoelectric device is mounted to a first side of a slug layer being opposite the submount layer, a thermoelectric device being mounted on a second side of the submount layer opposite the LED chip.

11. The LED chip package according to claim 10, wherein submount layer is silicon.

12. The LED chip package according to claim 9, wherein the thermoelectric device is located between the LED chip and a LED housing.
